(19) United States
(12) Patent Application Publication
(10) Pub. No.: US 2024/0288769 A1
(43) Pub. Date: Aug. 29, 2024

(54) METHOD OF MANUFACTURING SEMICONDUCTOR DEVICE AND PHOTORESIST COMPOSITION

(71) Applicant: TAIWAN SEMICONDUCTOR MANUFACTURING COMPANY, LTD., Hsinchu (TW)

(72) Inventors: Tzu-Yang LIN, Tainan City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 18/315,868

(22) Filed: May 11, 2023

Related U.S. Application Data
(60) Provisional application No. 63/484,152, filed on Feb. 9, 2023.

(51) Int. Cl. G03F 7/038; G03F 7/039; H01L 21/027; H01L 21/311; H01L 21/3213

(52) U.S. Cl. CPC G03F 7/038; G03F 7/039; H01L 21/0274; H01L 21/31144; H01L 21/32139

(57) ABSTRACT

A method of manufacturing a semiconductor device includes forming a photoresist layer on a target layer. The photoresist layer includes a polymer including first repeating units and second repeating units, the first repeating units are

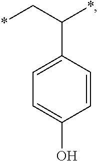

and the second repeating units are selected from the group consisting of

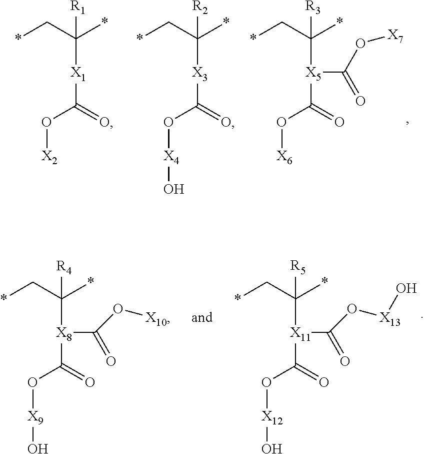

X₁ and X₃ are respectively an arylene group. X₅, X₈, and X₁₁ are respectively a trivalent functional group derived from an arene by removal of three hydrogen atoms. X₂, X₆, X₇, X₁₀, —X₄—OH, —X₉—OH, —X₁₂—OH, and —X₁₃—OH are respectively an acid labile group. R₁, R₂, R₃, R₄, and R₅ are respectively hydrogen or a methyl group. The photoresist layer is selectively exposed to a radiation. The photoresist layer is developed to form a patterned photoresist layer. The target layer is etched by using the patterned photoresist layer as an etching mask.

### PRIORITY CLAIM AND CROSS-REFERENCE

This application claims priority to U.S. Provisional Application Ser. No. 63/484,152, filed Feb. 9, 2023, which is herein incorporated by reference.

### BACKGROUND

As consumer devices have gotten smaller and smaller in response to consumer demand, the individual components of these devices are decreased in size as well. Semiconductor devices, which make up a major component of devices such as mobile phones, computer tablets, and the like, have been pressured to become smaller and smaller, with corresponding pressure on the individual devices (e.g., transistors, capacitors, resistors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that is not exposed, can be exploited to remove one region without removing the other. However, as the semiconductor industry has progressed into nanometer technology process nodes in pursuit of higher device density, higher performance, and lower costs, there have been challenges in reducing semiconductor feature size.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a process flow of manufacturing a semiconductor device in accordance with some embodiments of the present disclosure.

FIGS. 2, 3A, 3B, 4, 5, 6A, and 7A are diagrammatic fragmentary cross-sectional side views of a semiconductor device at various stages of fabrication in accordance with some embodiments of the present disclosure.

FIG. 6B and FIG. 6C are top views of the semiconductor device of FIG. 6A in accordance with some embodiments of the present disclosure.

FIG. 7B and FIG. 7C are top views of the semiconductor device of FIG. 7A in accordance with some embodiments of the present disclosure.

FIG. 8A is a perspective view of a semiconductor device at various stages of fabrication in accordance with some embodiments of the present disclosure.

FIG. 8B is a cross-sectional view of a semiconductor device taken along a line al-al of FIG. 8A.

FIG. 8C is a cross-sectional view of a semiconductor device taken along a line b1-b1 of FIG. 8A.

FIGS. 9-12 are diagrammatic fragmentary cross-sectional side views of a semiconductor device at various stages of fabrication in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

In a lithography process, a photoresist may be developed using either a positive-tone development (PTD) or a negative-tone development (NTD). For both PTD and NTD, the polymer of the photoresist needs a chemically amplified resist (CAR) reaction to produce polar switch and patterning. However, the CAR reaction may lead to certain undesirable side effects. For example, the polymer may contain an acid labile group (ALG). The ALG leaves the photoresist with the help of acid, and this is referred to as an ALG outgassing. The ALG outgassing may be undesirable because it may lead to shrinkage of a patterned photoresist layer after NTD, causing unsatisfactory photoresist patterning performance.

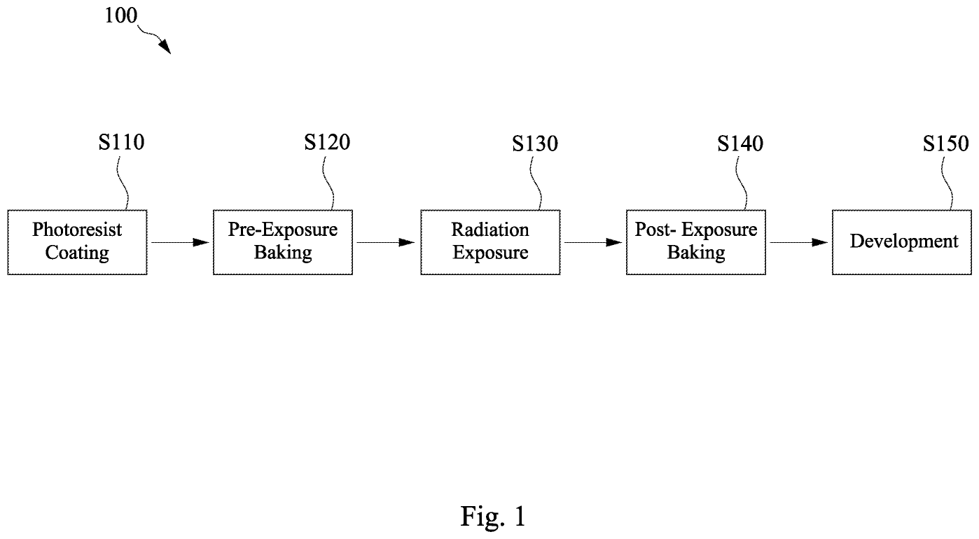

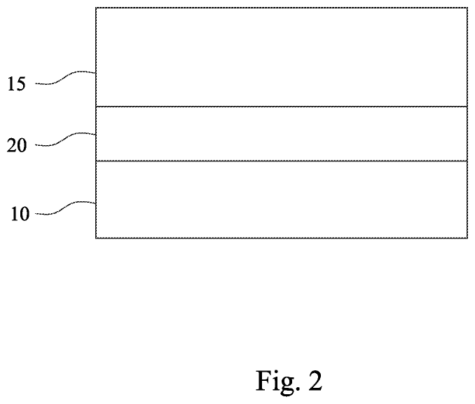

The present disclosure provides methods of manufacturing a semiconductor device to overcome the above problems. The present disclosure provides one or more of the following advantages: formation of a patterned photoresist layer with better critical dimension uniformity (CDU) and enhancement of the physical strength of the patterned photoresist layer. Therefore, the patterned photoresist layer can be used to pattern a target layer, e.g., a conductive layer, a dielectric layer, a semiconductor layer, or combinations thereof, to obtain a patterned layer with good quality. FIG. 1 illustrates a process flow 100 of manufacturing a semiconductor device in accordance with some embodiments of the present disclosure. FIGS. 2, 3A, 3B, 4, 5, 6A, and 7A are diagrammatic fragmentary cross-sectional side views of a semiconductor device at various stages of fabrication in accordance with some embodiments of the present disclosure.

In operation S110, a photoresist composition is coated on a surface of a target layer 20 (a layer to be patterned) to form a photoresist layer 15 on the target layer 20, and the target layer 20 is disposed on a substrate 10 as shown in FIG. 2. The photoresist layer 15 is formed over the substrate 10. In operation S120, the photoresist layer 15 undergoes a first baking operation (pre-exposure baking) to evaporate solvents in the photoresist composition in some embodiments. The photoresist layer 15 is baked at a temperature and time sufficient to cure and dry the photoresist layer 15. In some embodiments, the photoresist layer is heated to a temperature of about 40° C. and 120° C. for about 10 seconds to about 10 minutes. Heating at temperatures below the disclosed ranges or for less the than disclosed time duration may result in insufficient solvent removal from the photoresist layer. Heating at temperatures above the disclosed range or for longer than the disclosed time duration may result in deleterious chemical reactions in the photoresist layer 15. In some embodiments, the photoresist layer 15 has a thickness of less than or equal to about 75 nm. In some embodiments, the thickness of the photoresist layer 15 ranges from about 10 nm to about 75 nm. In some embodiments, the thickness of the photoresist layer 15 ranges from about 25 nm to about 65 nm. Thicknesses of the photoresist layer less than the disclosed ranges may result in insufficient photoresist coverage of the subsequently formed photoresist pattern. Thicknesses of the photoresist layer greater than the disclosed range may result in unnecessarily thick photoresist layers, higher cost of the photoresist material, and reduced pattern resolution.

In some embodiments, the substrate 10 may be a bulk semiconductor substrate including one or more semiconductor materials. In some embodiments, the substrate 10 includes a semiconductor wafer. In some embodiments, the substrate 10 includes a single crystalline semiconductor layer on at least it surface portion. The substrate 10 may include a single crystalline semiconductor material such as, but not limited to Si, Ge, SiGe, GaAs, InSb, GaP, GaSb, InAlAs, InGaAs, GaSbP, GaAsSb, InP, carbon doped silicon (Si:C), silicon germanium carbide, or other suitable semiconductor materials. In some embodiments, the substrate 10 is composed entirely of silicon. In some embodiments, the substrate 10 may include one or more epitaxial layers formed on a top surface of a bulk semiconductor substrate. In some embodiments, one or more epitaxial layers introduce strains in the substrate 10 for performance enhancement. For example, the epitaxial layer includes a semiconductor material different from that of the bulk semiconductor substrate, such as a layer of silicon germanium overlying bulk silicon or a layer of silicon overlying bulk silicon geranium. In some embodiments, the epitaxial layer(s) incorporated in the substrate 10 are formed by selective epitaxial growth, such as, for example, metalorganic vapor phase epitaxy (MOVPE), molecular beam epitaxy (MBE), hydride vapor phase epitaxy (HYPE), liquid phase epitaxy (LPE), metal-organic molecular beam epitaxy (MOMBE), or combinations thereof. In some embodiments, the substrate 10 may be a semiconductor-on-insulator (SOI) substrate. In some embodiments, the SOI substrate includes a semiconductor layer, such as a silicon layer formed on an insulator layer. In some embodiments, the insulator layer is a buried oxide (BOX) layer including silicon oxide or silicon germanium oxide. The insulator layer is provided on a handle substrate such as, for example, a silicon substrate. In some embodiments, the SOI substrate is formed using separation by implanted oxygen (SIMOX) or other suitable technique, such as wafer bonding and grinding.

In some embodiments, the substrate 10 includes one or more layers of at least one metal, metal alloy, and metal/nitride/sulfide/oxide/silicide having the formula MXₐ, where M is a metal and X is N, S, Se, O, or Si, and a is from about 0.4 to about 2.5. In some embodiments, the substrate 10 includes titanium, aluminum, cobalt, ruthenium, titanium nitride, tungsten nitride, tantalum nitride, or combinations thereof.

In some embodiments, the substrate 10 includes a dielectric having at least a silicon or metal oxide or nitride of the formula MX_{b}, where M is a metal or Si, X is N or O, and b ranges from about 0.4 to about 2.5. In some embodiments, the substrate 10 includes silicon dioxide, silicon nitride, aluminum oxide, hafnium oxide, lanthanum oxide, or combinations thereof.

In some embodiments, the target layer 20, which can be patterned, may also be referred to as a patternable layer. In some embodiments, the target layer 20 is a metallization layer or a dielectric layer, such as a passivation layer, disposed over a metallization layer. In some embodiments, the target layer 20 is a metallization layer, and the target layer 20 is formed of a conductive material using metallization processes and metal deposition techniques including chemical vapor deposition (CVD), atomic layer deposition (ALD), or physical vapor deposition (PVD)(sputtering). In some embodiments, the target layer 20 is substantially conductive or semi-conductive. The electrical resistance may be less than about 10³ ohm-meter. In some embodiments, the target layer 20 contains metal, metal alloy, or metal nitride/sulfide/selenide/oxide/silicide with the formula MXₐ, where M is a metal, and X is N, S, Se, O, or Si, and where “a” is in a range from about 0.4 to 2.5. For example, the target layer 20 may contain Cu, Ti, Al, Co, Ru, TiN, WN₂, or TaN. In some embodiments, the target layer 20 is a dielectric layer. In some embodiments, the target layer 20 serves as a hard mask layer including material(s) such as silicon oxide, silicon nitride, silicon oxynitride, or titanium nitride. In some embodiments, the target layer 20 severs as anti-reflection coating layer including nitrogen-free material(s), such as silicon oxide, silicon oxygen carbide, or plasma enhanced chemical vapor deposited silicon oxide. In some other embodiments, the target layer 20 contains a dielectric material with a dielectric constant in a range from about 1 to about 40. For example, the target layer 20 may contain SiO₂, silicon nitride, aluminum oxide, hafnium oxide, or lanthanum oxide. In some embodiments, the target layer 20 is formed by a deposition process such as, for example, CVD, PVD, or plasma enhanced chemical vapor deposition (PECVD).

In some embodiments, the photoresist layer 15 includes a photoresist composition. In some embodiments, the photoresist layer 15 is a negative photoresist layer or a negative tone photoresist layer, which has strong ability for patterning, especially for forming patterns that are not straight. The photoresist layer 15 or the photoresist composition includes a polymer including first repeating units and second repeating units. In some embodiments, the polymer consists essentially of the first repeating units and the second repeating units. In some embodiments, the polymer has a weight-average molecular weight between 5000 and 12000, such as 5000, 6000, 7000, 8000, 9000, 10000, 11000, or 12000. The first repeating units are

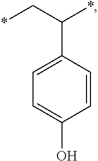

and the second repeating units are selected from the group consisting of

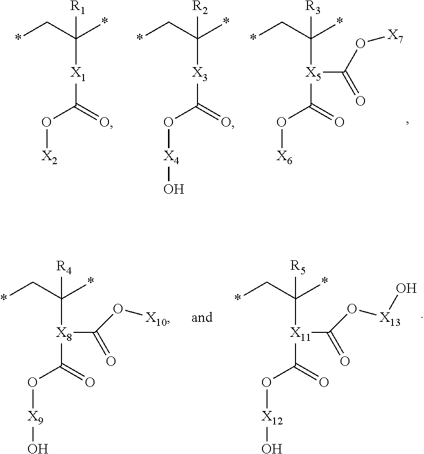

X₁ and X₃ are respectively an arylene group. The arylene group is a bivalent functional group derived from an arene by removal of two hydrogen atoms. X₅, X₈, and X₁₁ are respectively a trivalent functional group derived from an arene by removal of three hydrogen atoms. For example, the arene is benzene, toluene, ethylbenzene, p-xylene, or m-xylene, but is not limited thereto. X₂, X₆, X₇, X₁₀, —X₄—OH, —X₉—OH, —X₁₂—OH, and —X₁₃—OH are respectively an acid labile group (ALG). R₁, R₂, R₃, R₄, and R₅ are respectively hydrogen or a methyl group. In some embodiments, the second repeating units are 40 wt % to 70 wt % based on a total polymer weight. The disclosed weight percentage range allows for no significant volume loss in the photoresist layer 15 after the ALG group leaves. For example, the second repeating units are 40, 45, 50, 55, 60, 65, or 70 wt %.

In some embodiments, X₁ and X₃ are respectively a phenylene group, and X₅, X₈, and X₁₁ are respectively a trivalent functional group derived from benzene by removal of three hydrogen atoms. For example, the phenylene group is a p-phenylene group, a m-phenylene group, or a o-phenylene group. In some embodiments, the second repeating units are selected from the group consisting of

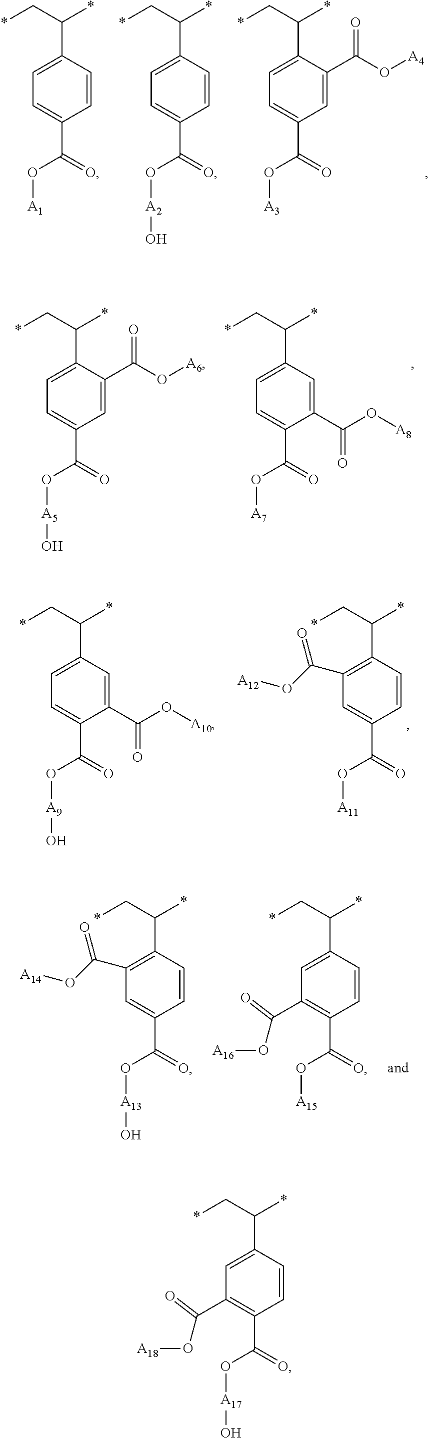

A₁, A₃, A₄, A₆, A₇, A₈, A₁₀, A₁₁, A₁₂, A₁₄, A₁₅, A₁₆, A₁₈, -A₂-OH, -A₅-OH, -A₉-OH, -A₁₃-OH, and -A₁₇-OH are respectively an acid labile group.

In some embodiments, A₁, A₃, A₄, A₆, A₇, A₈, A₁₀, A₁₁, A₁₂, A₁₄, A₁₅, A₁₆, A₁₈, -A₂-OH, -A₅-OH, -A₉-OH, -A₁₃-OH, -A₁₇-OH, X₂, X₆, X₇, X₁₀, —X₄—OH, —X₉—OH, —X₁₂—OH, and —X₁₃—OH are respectively a non-aromatic cycloalkyl group that is substituted by an alkyl group, a carboxyl group, a carbonyl group, a hydroxyl group, or combinations thereof. In some embodiments, the non-aromatic cycloalkyl group is monocyclic or polycyclic. For example, the non-aromatic cycloalkyl group is bicyclic.

In some embodiments, A₁, A₃, A₄, A₆, A₇, As, A₁₀, A₁₁, A₁₂, A₁₄, A₁₅, A₁₆, A₁₈, X₂, X₆, X₇, and X₁₀ are respectively a non-aromatic cycloalkyl group that is substituted by an alkyl group, a carboxyl group, a carbonyl group, or combinations thereof. In some embodiments, A₁, A₃, A₄, A₆, A₇, As, A₁₀, A₁₁, A₁₂, A₁₄, A₁₅, A₁₆, A₁₈, X₂, X₆. X₇, and X₁₀ are respectively

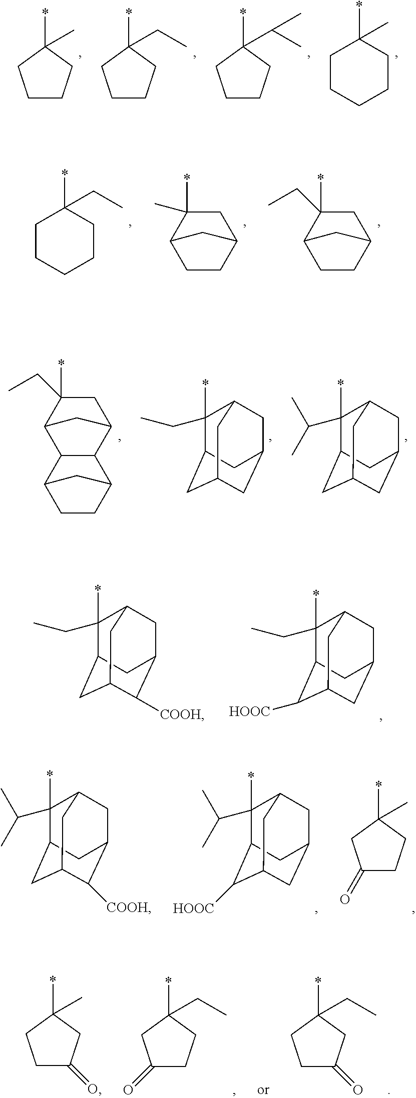

In some embodiments, A₂, A₅, A₉, A₁₃, A₁₇, X₄, X₉, X₁₂, and X₁₃ are respectively a bivalent functional group derived from a non-aromatic cycloalkyl group by removal of two hydrogen atoms, and the non-aromatic cycloalkyl group is substituted by an alkyl group, a carboxyl group, a carbonyl group, a hydroxyl group, or combinations thereof. In some embodiments, -A₂-OH, -A₅-OH, -A₉-OH, -A₁₃-OH, -A₁₇-OH, —X₄—OH, —X₉—OH, —X₁₂—OH, and —X₁₃—OH are respectively

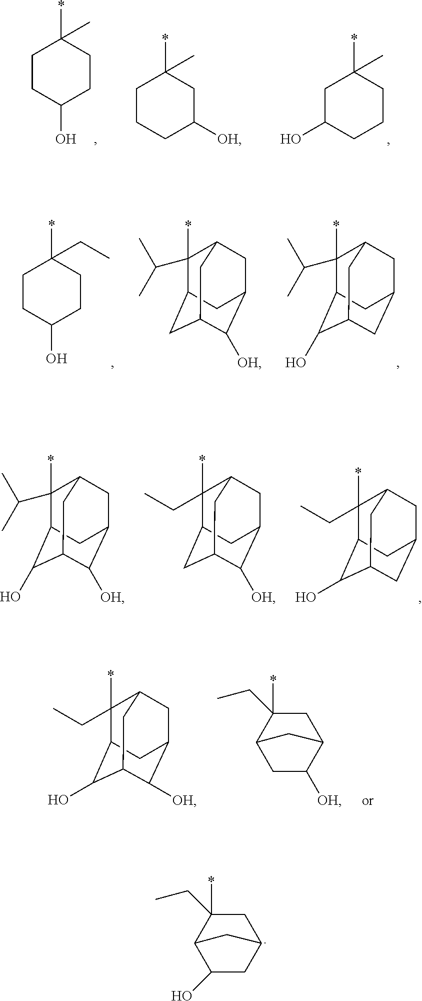

The hydroxyl group enables tuning of the dissolution rate of the ALG in the developer solvent. Moreover, the hydroxyl group can increase the adhesiveness of the photoresist layer 15 to underlying structures (e.g., target layer 20).

In some embodiments, the polymer further includes third repeating units. In other words, the polymer includes the first repeating units, the second repeating units, and the third repeating units. In some embodiments, the polymer consists essentially of the first repeating units, the second repeating units, and the third repeating units. In some embodiments, the polymer has a weight-average molecular weight between 5000 and 12000, such as 5000, 6000, 7000, 8000, 9000, 10000, 11000, or 12000. The third repeating units are

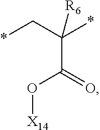

R₆ is respectively hydrogen or a methyl group, and X₁₄ is an acid labile group. In some embodiments, X₁₄ is a non-aromatic cycloalkyl group that is substituted by an alkyl group, a carboxyl group, a carbonyl group, a hydroxyl group, or combinations thereof. In some embodiments, the non-aromatic cycloalkyl group is monocyclic or polycyclic. For example, the non-aromatic cycloalkyl group is bicyclic. Please refer to the embodiments of X₂, X₆. X₇, X₁₀, —X₄—OH, —X₉—OH, —X₁₂—OH, and —X₁₃—OH for the embodiments of the X₁₄. In some embodiments, the second repeating units and the third repeating units are 40 wt % to 60 wt % based on a total polymer weight. The disclosed weight percentage range allows for no significant volume loss in the photoresist layer 15 after the ALG group leaves. For example, the second repeating units and the third repeating units are 40, 45, 50, 55, or 60 wt %.

In some embodiments, the polymer further includes fourth repeating units, the fourth repeating units are

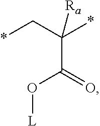

Rₐ is hydrogen or a methyl group, and L is a lactone moiety. In some embodiments, the polymer includes the first repeating units, the second repeating units, and the fourth repeating units. In some embodiments, the polymer consists essentially of the first repeating units, the second repeating units, and the fourth repeating units. In some embodiments, the polymer includes the first repeating units, the second repeating units, the third repeating units, and the fourth repeating units. In some embodiments, the polymer consists essentially of the first repeating units, the second repeating units, the third repeating units, and the fourth repeating units. In some embodiments, the polymer has a weight-average molecular weight between 5000 and 12000, such as 5000, 6000, 7000, 8000, 9000, 10000, 11000, or 12000. The lactone moiety may impart good lithographic performance to the photoresist layer. For example, the lactone moiety may improve dissolution in aqueous developer. In some embodiments, the lactone moiety is derived from a lactone that is five-membered or six-membered. For example, the lactone is γ-butyrolactone or δ-valerolactone. For example, the lactone moiety is derived from γ-butyrolactone by removal of one hydrogen atom or from ϵ-valerolactone by removal of one hydrogen atom.

In some embodiments, the photoresist composition includes one or more photoactive compounds (PACs) and the polymer of any of the embodiments mentioned above. The PACs are photoactive components, such as photoacid generators (PAGs), photobase generators (PBGs), free-radical generators, or the like. The PACs may be positive-acting or negative-acting. In some embodiments, the PACs are a photoacid generator. The PACs include halogenated triazine, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated ester, halogenated sulfonyloxy dicarboximide, diazodisulfone, α-cyanooxyamine-sulfonate, imidesulfonate, ketodiazosulfone, sulfonyldiazoester, 1,2-di(arylsulfonyl)hydrazine, nitrobenzyl ester, s-triazine derivatives, or combinations thereof.

Specific examples of photoacid generators include α-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-toluenesulfonyloxy)-acetate and t-butyl-α-(p-toluenesulfonyloxy)-acetate, triarylsulfonium and diaryliodonium hexafluoroantimonate, hexafluoroarsenate, trifluoromethanesulfonate, iodonium perfluorooctanesulfonate, N-camphorsulfonyloxynaphthalimide, N-pentafluorophenylsulfonyloxynaphthalimide, ionic iodonium sulfonate such as diaryl iodonium (alkyl or aryl)sulfonate and bis-(di-t-butylphenyl)iodonium camphanylsulfonate, perfluoroalkanesulfonate such as perfluoropentanesulfonate, perfluorooctanesulfonate, perfluoromethanesulfonate, aryl (e.g., phenyl or benzyl)triflate such as triphenylsulfonium triflate or bis-(t-butylphenyl)iodonium triflate; pyrogallol derivatives (e.g., trimesylate of pyrogallol), trifluoromethanesulfonate ester of hydroxyimide, α,α′-bis-sulfonyl-diazomethane, sulfonate ester of nitro-substituted benzyl alcohol, naphthoquinone-4-diazide, alkyl disulfone, combinations thereof, or the like.

Structures of photoacid generators according to the embodiments of the disclosure include:

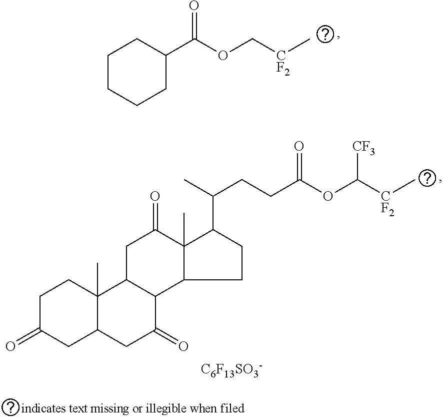

or a combination thereof.

In some embodiments, the PACs are free-radical generators. The PACs include n-phenylglycine; aromatic ketone, including benzophenone, N, N′-tetramethyl-4,4′-diaminobenzophenone, N,N′-tetraethyl-4,4′-diaminobenzophenone, 4-methoxy-4′-dimethylaminobenzo-phenone, 3,3′-dimethyl-4-methoxybenzophenone, p,p′-bis(dimethylamino)benzo-phenone, p, p′-bis(diethylamino)-benzophenone; anthraquinone, 2-ethylanthraquinone; naphthaquinone; phenanthraquinone; benzoin, benzoinmethylether, benzoinisopropylether, benzoin-n-butylether, benzoin-phenylether, methylbenzoin, ethylbenzoin; benzyl derivatives, including benzyl diphenyl disulfide and benzyl dimethyl ketal; acridine derivatives, including 9-phenylacridine and 1,7-bis(9-acridinyl)heptane; thioxanthones, including 2-chlorothioxanthone, 2-methylthioxanthone, 2,4-diethylthioxanthone, 2,4-dimethylthioxanthone, and 2-isopropylthioxanthone; acetophenones, including 1,1-dichloroacetophenone, p-t-butyldichloro-acetophenone, 2,2-diethoxyacetophenone, 2,2-dimethoxy-2-phenylacetophenone, and 2,2-dichloro-4-phenoxyacetophenone; 2,4,5-triarylimidazole dimers, including 2-(o-chlorophenyl)-4,5-diphenylimidazole dimer, 2-(o-chlorophenyl)-4,5-di-(m-methoxyphenyl imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, 2-(2,4-dimethoxyphenyl)-4,5-diphenylimidazole dimer, and 2-(p-methylmercaptophenyl)-4,5-diphenylimidazole dimmer; combinations thereof, or the like.

In some embodiments, the PACs are photobase generators. The PACs includes quaternary ammonium dithiocarbamates, aminoketone, oxime-urethane containing molecules such as dibenzophenoneoxime hexamethylene diurethan, ammonium tetraorganylborate salts, N-(2-nitrobenzyloxycarbonyl)cyclic amine, combinations thereof, or the like.

As one of ordinary skill in the art will recognize, the chemical compounds listed herein are merely intended as illustrated examples of the PACs and are not intended to limit the embodiments to only those PACs specifically described. Rather, any suitable PAC may be used, and all such PACs are fully intended to be included within the scope of the present embodiments.

In some embodiments, the photoresist layer 15 or the photoresist composition further includes a solvent in order to achieve a homogenous composition to ensure that there are no defects caused by uneven mixing or a nonhomogeneous photoresist composition. The solvent can be any suitable solvent. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), and 2-heptanone (MAK).

In some embodiments, the photoresist layer 15 or the photoresist composition further includes a cross-linking agent. The cross-linking agent can increase the molecular weight of the polymer products by the cross-linking reaction and increases the overall linking density of the photoresist. Such an increase in density and linking density helps to improve the photoresist pattern. For example, the cross-linking agent has the following structure:

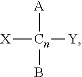

in which C is carbon, n ranges from 1 to 15. A and B independently include a hydrogen atom, a hydroxyl group, a halide, an aromatic carbon ring, or a straight or cyclic alkyl, alkoxyl/fluoro, alkyl/fluoroalkoxyl chain having a carbon number of between 1 and 12, and each carbon C contains A and B. A first terminal carbon C at a first end of a carbon C chain includes X, and a second terminal carbon C at a second end of the carbon chain includes Y, in which X and Y independently include an amine group, a thiol group, a hydroxyl group, an isopropyl alcohol group, or an isopropyl amine group, except when n=1 then X and Y are bonded to the same carbon C. Specific examples of cross-linking agent include the following:

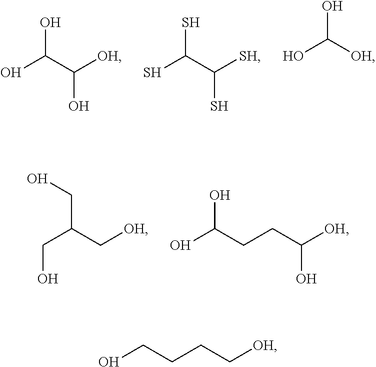

or combinations thereof.

In some embodiments, when EUV radiation is used, the photoresist composition or the photoresist layer 15 is a metal-containing resist. The metal-containing resists include metallic cores complexed with one or more ligands in a solvent. In some embodiments, the resist includes metal particles. In some embodiments, the metal particles are nanoparticles. As used herein, nanoparticles are particles having an average particle size between about 1 nm and about 20 nm. In some embodiments, the metallic cores, including from 1 to about 18 metal particles, are complexed with one or more organic ligands in a solvent. In some embodiments, the metallic cores include 3, 6, 9, or more metal nanoparticles complexed with one or more organic ligands in a solvent. In some embodiments, the metal particle is one or more of titanium (Ti), zinc (Zn), zirconium (Zr), nickel (Ni), cobalt (Co), manganese (Mn), copper (Cu), iron (Fe), strontium (Sr), tungsten (W), vanadium (V), chromium (Cr), tin (Sn), hafnium (Hf), indium (In), cadmium (Cd), molybdenum (Mo), tantalum (Ta), niobium (Nb), aluminum (Al), cesium (Cs), barium (Ba), lanthanum (La), cerium (Ce), silver (Ag), antimony (Sb), combinations thereof, and oxides thereof. In some embodiments, the metal particles include one or more selected from the group consisting of Ce, Ba, La, Ce, In, Sn, Ag, Sb, and oxides thereof.

In some embodiments, the metallic core is complexed by a thermally stable ligand, in which the thermally stable ligand includes branched or unbranched, cyclic or non-cyclic, saturated organic groups, including C1-C7 alkyl groups or C1-C7 fluoroalkyl groups. The C1-C7 alkyl groups or C1-C7 fluoroalkyl groups include one or more substituents selected from the group consisting of —CF₃, —SH, —OH, —O, —S—, —P—, —PO₂, —C(═O)SH, —C(═O)OH, —C(═O)O—, —O—, —N—, —C(═O)NH, —SO₂OH, —SO₂SH, —SOH, and —SO₂—. In some embodiments, the ligand includes one or more substituents selected from the group consisting of —CF₃, —OH, —SH, and —C(═O)OH. In some embodiments, the ligand is a carboxylic acid or a sulfonic acid ligand. For example, in some embodiments, the ligand is a methacrylic acid. In some embodiments, the metal particles are nanoparticles, and the metal nanoparticles are complexed with ligands including aliphatic or aromatic groups. The aliphatic or aromatic groups may be unbranched or branched with cyclic or noncyclic saturated pendant groups containing 1-9 carbons, including alkyl groups, alkenyl groups, and phenyl groups. The branched groups may be further substituted with oxygen or halogen. In some embodiments, each metal particle is complexed by 1 to 25 ligand units. In some embodiments, each metal particle is complexed by 3 to 18 ligand units.

In some embodiments, the photoresist composition further includes an acid generator or a base generator, such as a thermal acid generator (TAG) or a thermal base generator (TBG). In some embodiments, TAG includes

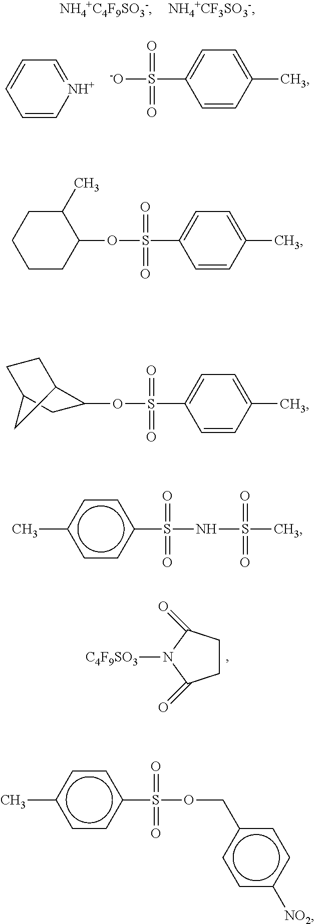

or combinations thereof. In some embodiments, the TBG includes

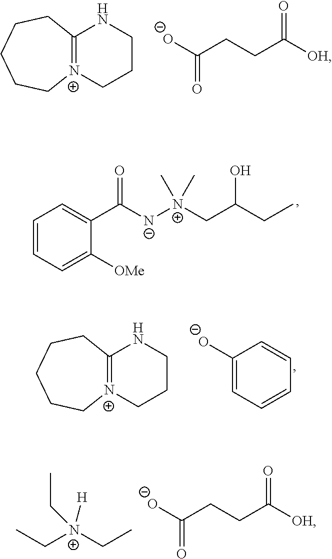

N-(p-nitropheny)-2,6-dimethylpiperidine (NDP), or combinations thereof.

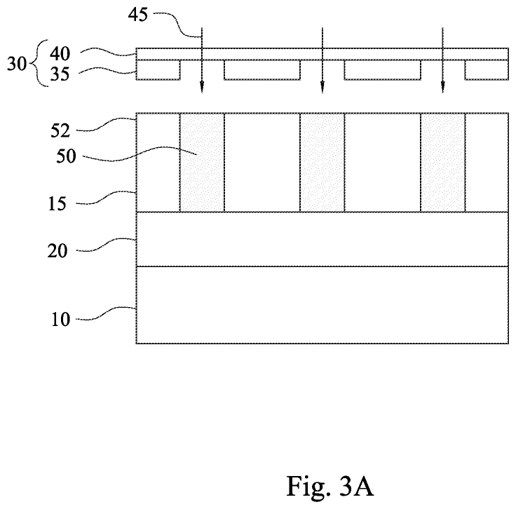

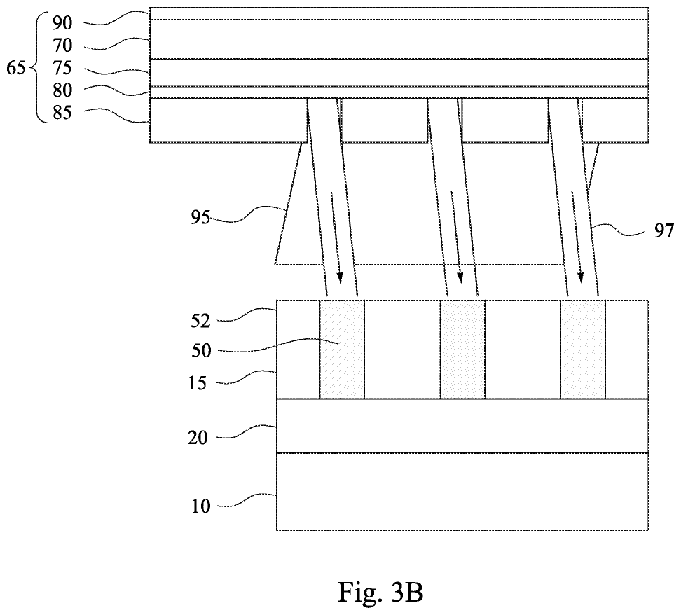

After the first baking operation S120, the photoresist layer 15 is selectively exposed to a radiation 45/97 (see FIGS. 3A and 3B) in operation S130. In some embodiments, the photoresist layer 15 is selectively exposed to ultraviolet radiation. In some embodiments, the ultraviolet radiation is deep ultraviolet radiation (DUV). In some embodiments, the ultraviolet radiation is extreme ultraviolet (EUV) radiation. In some embodiments, the radiation is an electron beam.

As shown in FIG. 3A, the radiation 45 passes through a photomask 30 before irradiating the photoresist layer 15 in some embodiments. In some embodiments, the photomask 30 has a pattern to be replicated in the photoresist layer 15. The pattern is formed by an opaque pattern 35 on a photomask substrate 40, in some embodiments. The opaque pattern 35 may be formed by a material opaque to ultraviolet radiation, such as chromium, while the photomask substrate 40 is formed of a material that is transparent to ultraviolet radiation, such as fused quartz. The photoresist layer 15 is selectively exposed to form at least one exposed region 50 and at least one unexposed region 52.

As shown in FIG. 3B, for example, the exposure is performed by using extreme ultraviolet (EUV) lithography. In an EUV lithography operation, a reflective photomask 65 is used to form the patterned exposure light. The reflective photomask 65 includes a low thermal expansion glass substrate 70, on which a reflective multilayer 75 of Si and Mo is formed. A capping layer 80 and an absorber layer 85 are formed on the reflective multilayer 75. A rear conductive layer 90 is formed on the back side of the low thermal expansion glass substrate 70. In the extreme ultraviolet lithography, extreme ultraviolet radiation 95 is directed towards the reflective photomask 65 at an incident angle of about 6°. A portion 97 of the EUV radiation is reflected by the reflective multilayer 75 towards the photoresist layer 15 to form at least one exposed region 50 and at least one unexposed region 52, while a portion of the extreme ultraviolet radiation incident upon the absorber layer 85 is absorbed by the photomask. In some embodiments, additional optics, including mirrors, are between the reflective photomask 65 and the photoresist-coated substrate 10.

The region of the photoresist layer exposed to the radiation 45/97 undergoes a chemical reaction thereby changing its solubility in a subsequently applied developer relative to the region of the photoresist layer not exposed to the radiation 45/97. In some embodiments, the portion of the photoresist layer exposed to radiation 45/97 undergoes a crosslinking reaction. In the case of negative photoresist, the irradiated areas are made insoluble in a developer and the non-irradiated areas remain soluble in a developer.

Next, the photoresist layer 15 undergoes a post-exposure bake (PEB) (or second baking operation) in operation S140. In some embodiments, the photoresist layer 15 is heated to a temperature of about 50° C. and 160° C. for about 20 seconds to about 120 seconds. The post-exposure baking may be used in order to assist in the generating, dispersing, and reacting of the acid/base/free radical generated from the impingement of the radiation 45/97 upon the photoresist layer 15 during the exposure. Such assistance helps to create or enhance chemical reactions, which generate chemical differences between the exposed regions 50 and the unexposed regions 52 within the photoresist layer. These chemical differences also cause differences in the solubility between the exposed regions 50 and the unexposed regions 52. Heating at temperatures below the disclosed ranges or for less the than disclosed time duration may result in insufficient generation, dispersing, and reaction of the acid/base/free radical. Heating at temperatures above the disclosed range or for longer than the disclosed time duration may result in deleterious chemical reactions in the photoresist layer or may unnecessarily increase the cost and processing time of the semiconductor device.

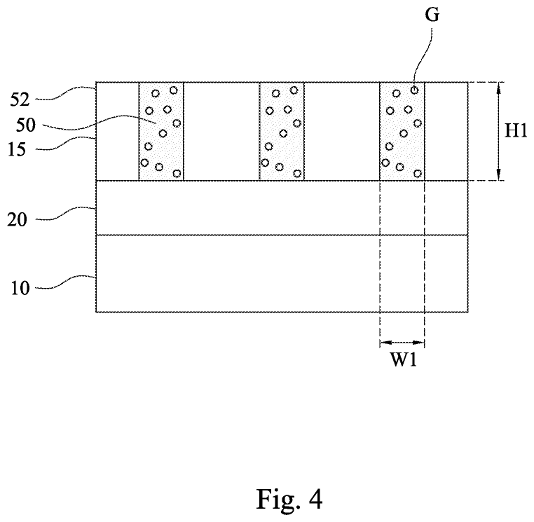

The polymer in the photoresist layer 15 can react with an acid or a base, which can be generated by an acid generator or a base generator in the photoresist composition. The acid or base can cleave the ALG groups. As shown in FIG. 4, the cleaving releases the ALG groups, i.e., creating ALG outgassing G. In some embodiments, the PEB may produce ALG outgassing. The ALG outgassing G may degrade lithography performance. For example, a patterned photoresist layer may have rough edges. However, the polymer of the present disclosure includes bulky groups derived from arenes, for example, X₁, X₃, X₅, X₈, X₁₁, or combinations thereof, and therefore the volume of the photoresist layer 15 or the volume of the exposed regions 50 is not easily affected by the ALG outgassing G. Therefore, shrinkage of the patterned photoresist layer after negative tone development (NTD) can be reduced or prevented. In other words, the percentage of volume loss of the patterned photoresist layer can be lowered. The patterned photoresist layer can thus have better critical dimension uniformity (CDU) and better physical strength.

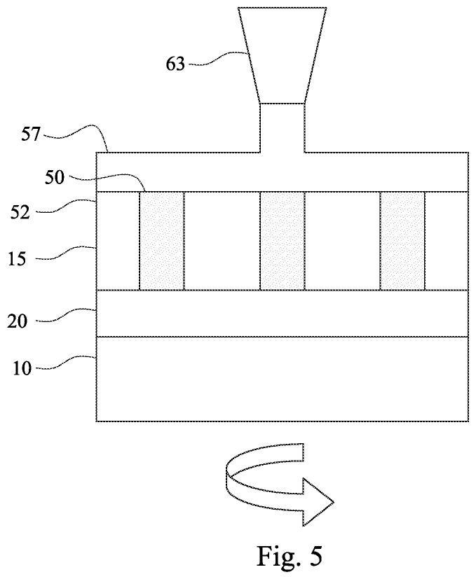

The selectively exposed photoresist layer is subsequently developed by applying a developer to the selectively exposed photoresist layer in operation S150. As shown in FIG. 5, a developer 57 is supplied from a dispenser 63 to the photoresist layer 15. In some embodiments, the photoresist layer 15 is a negative photoresist layer or a negative tone photoresist layer. The developer 57 is a negative tone developer. The developer 57 may be an organic solvent or a critical fluid. In some embodiments, the developer 57 includes one or more selected from the group consisting of hexane, heptane, octane, toluene, xylene, dichloromethane, chloroform, carbon tetrachloride, trichloroethylene, and similar hydrocarbon solvents; critical carbon dioxide, methanol, ethanol, propanol, butanol, and similar alcohol solvents; diethyl ether, dipropyl ether, dibutyl ether, ethyl vinyl ether, dioxane, propylene oxide, tetrahydrofuran, cellosolve, methyl cellosolve, butyl cellosolve, methyl carbitol, diethylene glycol monoethyl ether, and similar ether solvents; acetone, methyl ethyl ketone, methyl isobutyl ketone, isophorone, cyclohexanone, and similar ketone solvents; methyl acetate, ethyl acetate, propyl acetate, butyl acetate, and similar ester solvents; and pyridine, formamide, N,N-dimethyl formamide, and the like.

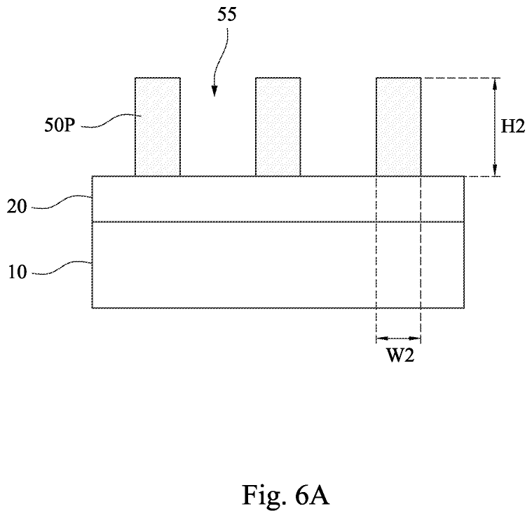

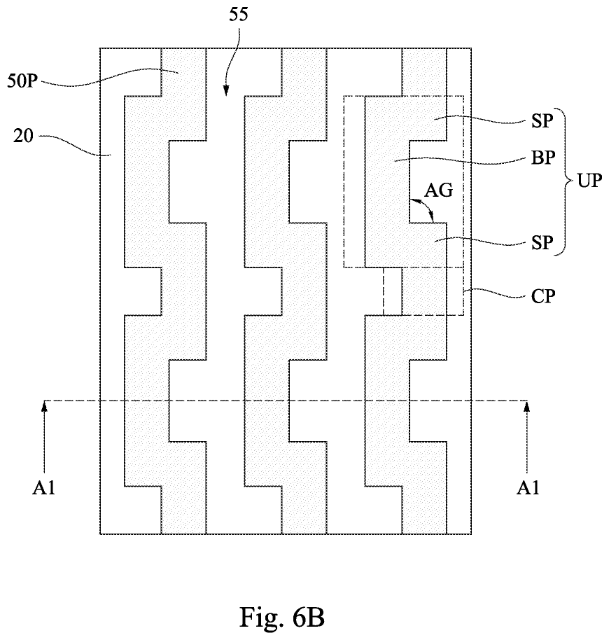

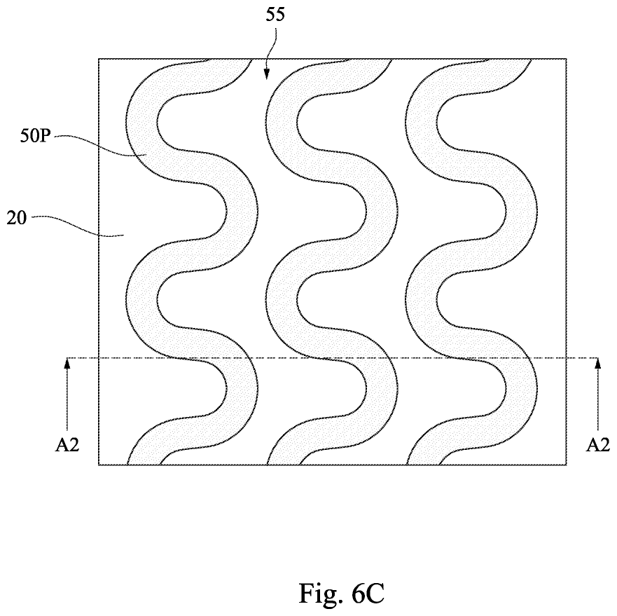

As shown in FIG. 6A, in some embodiments, the unexposed portions 52 are removed by the developer 57 to form a patterned photoresist layer 50P. The patterned photoresist layer 50P also can be regarded as the exposed regions 50 of the photoresist layer 15. In the patterned photoresist layer 50P, a pattern of openings 55 exposes the target layer 20. The polymer in the patterned photoresist layer 50P includes groups with larger volumes. Theses groups are derived from arenes, for example, X₁, X₃, X₅, X₈, X₁₁, or combinations thereof, and therefore the volume of the patterned photoresist layer 50P is not easily affected by the ALG outgassing. For example, shrinkage of the patterned photoresist layer 50P after negative tone development (NTD) can be reduced or prevented. In other words, the percentage of volume loss of the patterned photoresist layer 50P can be lowered. The patterned photoresist layer 50P can thus have better critical dimension uniformity (CDU) and better physical strength. Please refer to FIG. 4 and FIG. 6A. A width W1 of the exposed region 50 of the photoresist layer 15 is substantially equal to or similar to a width W2 of the patterned photoresist layer 50P. A height H1 of the exposed region 50 of the photoresist layer 15 is substantially equal to or similar to a height H2 of the patterned photoresist layer 50P.

In some embodiments, FIG. 6A is a cross-sectional view of the semiconductor device taken along a line A1-A1 of FIG. 6B. As shown in FIG. 6B, in some embodiments, the patterned photoresist layer 50P has U-shaped portions UP and connecting portions CP between the U-shaped portions UP in a top view. One U-shaped pattern US has one bottom portion BP and two side portions SP extending from the ends of the bottom portion BP. The bottom portion BP and one of the side portions SP form an angle AG. In some embodiments, the angle AG is equal to or greater than 90 degrees and less than 180 degrees, such as 90, 100, 110, 120, 130, 140, 150, 160, or 170 degrees. In some embodiments, FIG. 6A is a cross-sectional view of the semiconductor device taken along a line A2-A2 of FIG. 6C. In some other embodiments, the patterned negative photoresist layer 50P has wavy patterns as shown in FIG. 6C. In other words, the patterned photoresist layer 50P includes bent portions connected with each other.

Reference is made to FIGS. 6B and 6C. The patterned photoresist layers 50P shown in FIG. 6B and FIG. 6C are not straight. Compared to straight photoresist patterns, the structural parameters of a photoresist pattern that is not straight, such as height and/or width, may be more likely affected by an ALG outgassing. For example, the width of the photoresist pattern may be reduced, resulting in weak points in the photoresist pattern. However, the polymer in the patterned photoresist layers 50P shown in FIG. 6B and FIG. 6C include bulky groups derived from arenes, for example, X₁, X₃, X₅, X₈, X₁₁, or combinations thereof. Therefore, the volume loss of the patterned photoresist layers 50P can be reduced, and the height and the width of the patterned photoresist layers 50P are not easily affected by the ALG outgassing. For example, the height and the width of the patterned photoresist layers 50P are substantially uniform. The CDU of the patterned photoresist layer 50P can be improved, and the physical strength can be enhanced accordingly.

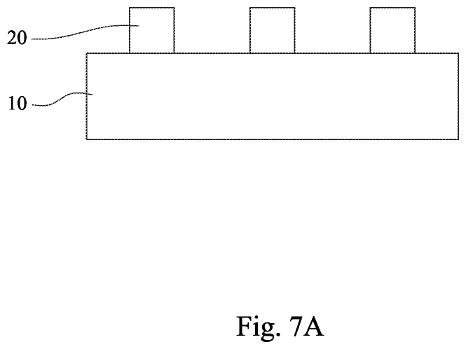

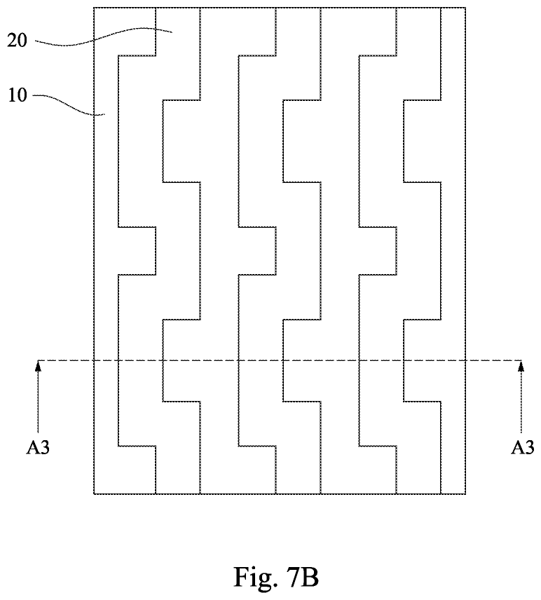

As shown in FIG. 7A, the pattern of the patterned photoresist layer 50P (i.e., the pattern of the exposed regions 50) is transferred to the target layer 20 using an etching operation, and the photoresist layer is removed. In other words, the target layer 20 is etched by using the patterned photoresist layer 50P as an etching mask. The pattern of the openings 55 shown in FIG. 6A is extended into the target layer 20 by etching using one or more suitable etchants. The patterned photoresist layer 50P is at least partially removed during the etching operation in some embodiments. In other embodiments, the patterned photoresist layer 50P is removed after etching the target layer 20 by using a suitable photoresist stripper solvent or by a photoresist ashing operation.

In some embodiments, FIG. 7A is a cross-sectional view of the semiconductor device taken along a line A3-A3 of FIG. 7B. As shown in FIG. 7B, the target layer 20 is etched by using the patterned photoresist layer 50P shown in FIG. 6B as an etching mask. Therefore, the patterns of the patterned photoresist layer 50P having U-shaped portions UP and connecting portions CP are transferred to the target layer 20. In some embodiments, FIG. 7A is a cross-sectional view of the semiconductor device taken along a line A4-A4 of FIG. 7C. As shown in FIG. 7C, the target layer 20 is etched by using the patterned photoresist layer 50P shown in FIG. 6C as an etching mask. Therefore, the wavy patterns of the patterned photoresist layer 50P are transferred to the target layer 20.

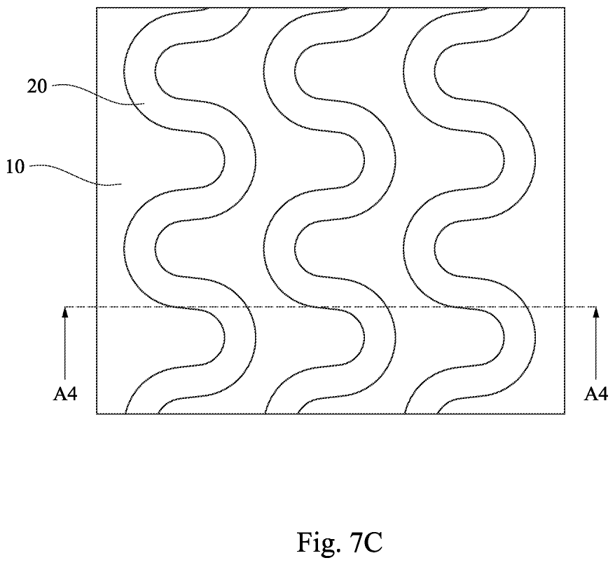

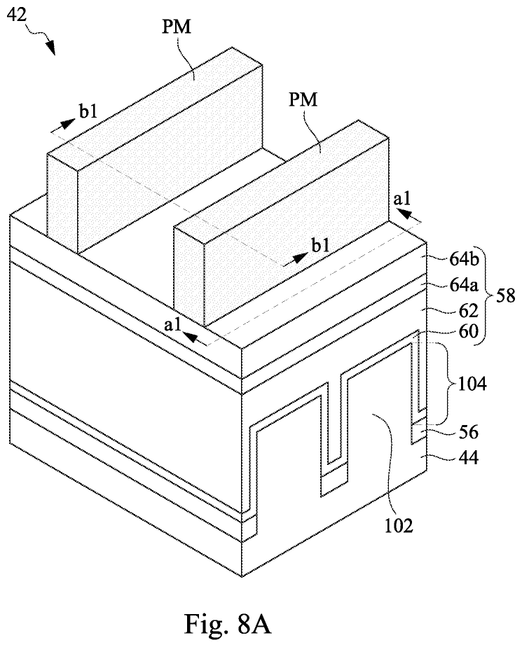

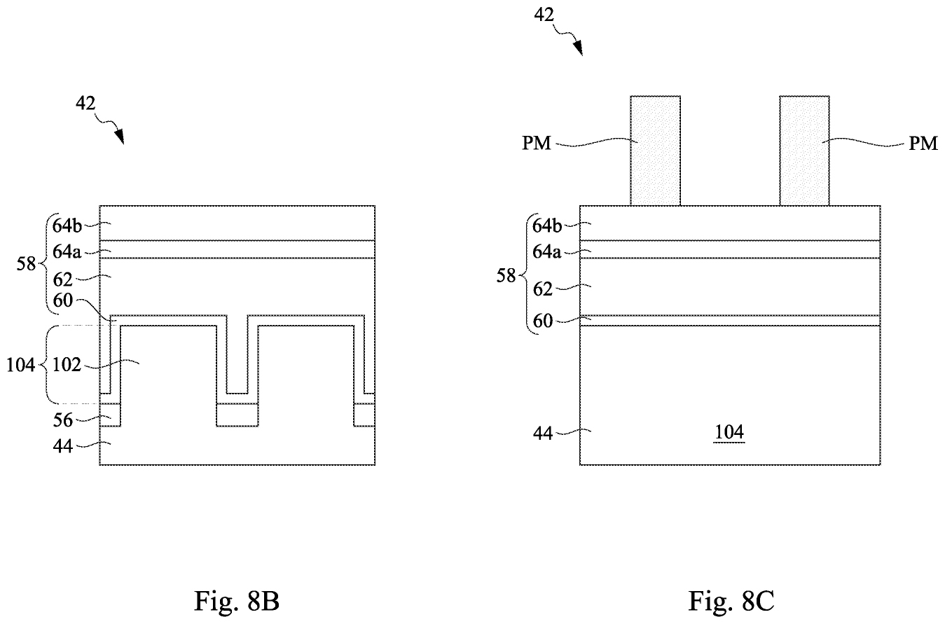

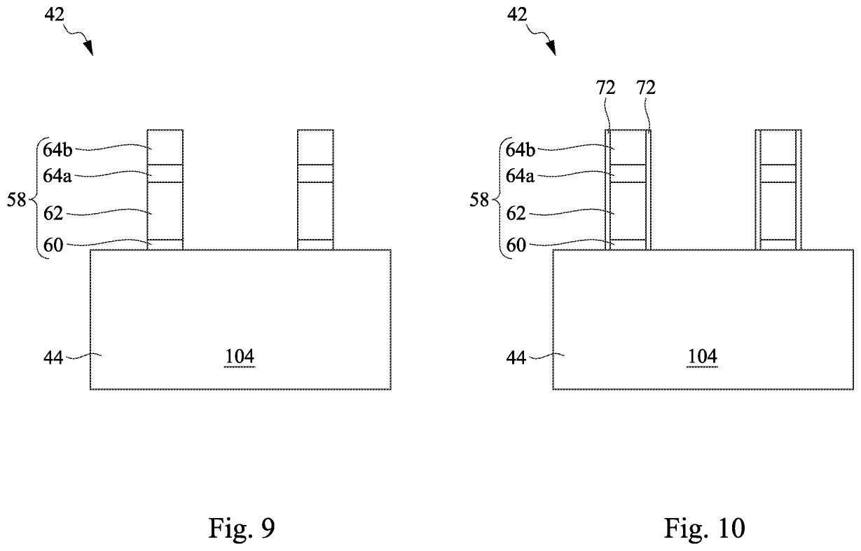

FIG. 8A is a perspective view of the semiconductor device 42 at various stages of fabrication in accordance with some embodiments of the present disclosure. FIG. 8B is a cross-sectional view of the semiconductor device 42 taken along a line a1-a1 of FIG. 8A. FIG. 8C is a cross-sectional view of the semiconductor device 42 taken along a line b1-b1 of FIG. 8A. FIGS. 9-12 are diagrammatic fragmentary cross-sectional side views of the semiconductor device 42 at various stages of fabrication in accordance with some embodiments of the present disclosure. Referring to FIGS. 8A-8C, a dummy gate stack 58 is formed on top surfaces and sidewalls of the protruding fins 104 of the semiconductor strips 102. The dummy gate stack 58 may include a dummy gate dielectric 60 and a dummy gate electrode 62 on the dummy gate dielectric 60. The dummy gate dielectric 60 may be, for example, silicon oxide, silicon nitride, a combination thereof, or the like, and may be deposited or thermally grown according to acceptable techniques.

The dummy gate electrode 62 may be deposited over the dummy gate dielectric 60 and then planarized, such as by a CMP. The dummy gate electrode 62 may be deposited by PVD, CVD, sputter deposition, or other techniques for depositing the selected material. The dummy gate electrode 62 may be formed, for example, using polysilicon, and other materials may also be used. The dummy gate electrode 62 may be made of other materials that have a high etching selectivity from the etching of STI regions 56. The dummy gate stack 58 may also include hard mask layers 64a and 64b over the dummy gate electrode 62. The hard mask layers 64a and 64b may be formed of silicon nitride and silicon oxide, respectively. The dummy gate stack 58 may cross over a single one or a plurality of protruding fins 104 and/or STI regions 56.

A patterned mask PM is formed on the dummy gate stack 58. The above discussions of the patterned photoresist layer 50P can be applied to the patterned mask PM, unless mentioned otherwise. In other words, the patterned mask PM can be formed by the embodiments shown in FIGS. 1-6C. Therefore, the patterned mask PM has higher rigidity and better CDU, resulting in pattern with good quality formed by the patterned mask PM.

In FIG. 9, using the patterned mask PM as an etching mask, the pattern of the patterned mask PM is extended into the dummy gate stack 58 by etching, using one or more suitable etchants. The patterned mask PM is at least partially removed during the etching operation in some embodiments. In other embodiments, the patterned mask PM is removed after etching the dummy gate stack 58 by using a suitable photoresist stripper solvent or by a photoresist ashing operation.

Next, as illustrated in FIG. 10, gate spacers 72 are formed on sidewalls of the dummy gate stack 58. In some embodiments of the gate spacer formation step, a spacer material layer is deposited on the substrate 44 and the dummy gate stack 58. Please refer to the embodiments of the substrate 10 for the embodiments of the substrate 44. The spacer material layer may be a conformal layer that is subsequently etched back to form gate spacers 72. The spacer material layer is made of a low-k dielectric material. The low-k dielectric material has a dielectric constant (k value) of lower than about 3.5. Suitable materials for the low-k dielectric material may include, but are not limited to, doped silicon dioxide, fluorinated silica glass (FSG), carbon-doped silicon dioxide, porous silicon dioxide, porous carbon-doped silicon dioxide, SiLK™ (an organic polymeric dielectric distributed by Dow Chemical of Michigan), Black Diamond (a product of Applied Materials of Santa Clara, Calif.), Xerogel, Aerogel, amorphous fluorinated carbon, Parylene, bis-benxocyclocutenes (BCB), polyimide, polynoroboneses, benzocyclocutene, PTFE, porous SiLK, hydrogen silsesquioxane (HSQ), methylsilsesquioxane (MSQ), and/or combinations thereof. By way of example and not limitation, the spacer material layer may be formed using processes such as, CVD process, a subatmospheric CVD (SACVD) process, a flowable CVD process, an ALD process, a physical vapor deposition (PVD) process, or other suitable process. An anisotropic etching process is then performed on the deposited spacer material layer to expose portions of the fins 104 not covered by the dummy gate stack 58 (e.g., in source/drain regions of the fins 104). Portions of the spacer material layer directly above the dummy gate stack 58 may be completely removed by this anisotropic etching process. Portions of the spacer material layer on sidewalls of the dummy gate stack 58 may remain, forming gate spacers, which are denoted as the gate spacers 72, for the sake of simplicity. In some embodiments, the gate spacers 72 may be used to offset subsequently formed doped regions, such as source/drain regions. The gate spacers 72 may further be used for designing or modifying the source/drain region profile.

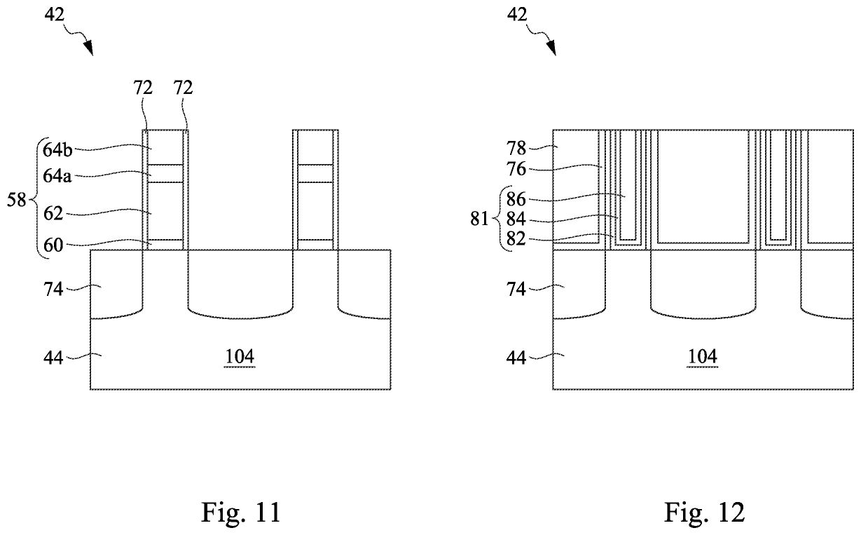

In FIG. 11, after formation of the gate spacers 72 is completed, source/drain epitaxial structures 74 are formed on source/drain regions of the protruding fins 104 that are not covered by the dummy gate stack 58 and the gate spacers 72. In some embodiments, formation of the source/drain epitaxial structures 74 includes recessing source/drain regions of the fins 104, followed by epitaxially growing semiconductor materials in the recessed source/drain regions of the fins 104. The source/drain epitaxial structures 74 are on opposite sides of the dummy gate stack 58.

The source/drain regions of the fins 104 can be recessed using suitable selective etching processing that attacks the fins 104, but hardly attacks the gate spacers 72 and the hard mask layer 64b of the dummy gate stack 58. For example, recessing the fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like, and the etchant gas may be fluorine, chlorine, bromine, combinations thereof, or the like, which etches the protruding fins 104 at a faster etch rate than it etches the gate spacers 72 and the hard mask layer 64b of the dummy gate stack 58. In some other embodiments, recessing the protruding fins 104 may be performed by a wet chemical etch, such as ammonium peroxide mixture (APM), NH₄OH, tetramethylammonium hydroxide (TMAH), combinations thereof, or the like, which etches the fins 104 at a faster etch rate than it etches the gate spacers 72 and the hard mask layer 64b of the dummy gate stack 58. In some other embodiments, recessing the protruding fins 104 may be performed by a combination of a dry chemical etch and a wet chemical etch.

Once recesses are created in the source/drain regions of the fins 104, source/drain epitaxial structures 74 are formed in the source/drain recesses in the fins 104 by using one or more epitaxy or epitaxial (epi) processes that provide one or more epitaxial materials on the protruding fins 104. During the epitaxial growth process, the gate spacers 72 limit one or more epitaxial materials to source/drain regions in the fins 104. In some embodiments, the lattice constants of the source/drain epitaxial structures 74 are different from the lattice constant of the fins 104, so that the channel region in the fins 104 and between the source/drain epitaxial structures 74 can be strained or stressed by the source/drain epitaxial structures 74 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the fins 104.

In some embodiments, the source/drain epitaxial structures 74 may include Ge, Si, GaAs, AlGaAs, SiGe, GaAsP, SiP, or other suitable materials. The source/drain epitaxial structures 74 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 74 are not in-situ doped, an implantation process (i.e., a junction implant process) is performed to dope the source/drain epitaxial structures 74. In some exemplary embodiments, the source/drain epitaxial structures 74 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain epitaxial structures 74 are formed, an annealing process can be performed to activate the p-type dopants or n-type dopants in the source/drain epitaxial structures 74. The annealing process may be, for example, a rapid thermal anneal (RTA), a laser anneal, a millisecond thermal annealing (MSA) process, or the like.

Next, in FIG. 12, a contact etch stop layer (CESL) 76 and an interlayer dielectric (ILD) layer 78 are formed on the substrate 44 in sequence. In some examples, the CESL 76 includes a silicon nitride layer, silicon oxide layer, a silicon oxynitride layer, and/or other suitable materials having a different etch selectivity than the ILD layer 78. The CESL 76 may be formed by plasma-enhanced chemical vapor deposition (PECVD) process and/or other suitable deposition or oxidation processes. In some embodiments, the ILD layer 78 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 76. The ILD layer 78 may be deposited by a PECVD process or other suitable deposition technique. In some embodiments, after formation of the ILD layer 78, the wafer may be subject to a high thermal budget process to anneal the ILD layer 78.

In some examples, after forming the ILD layer 78, a planarization process may be performed to remove excessive materials of the ILD layer 78 and the CESL 76. For example, a planarization process includes a chemical mechanical planarization (CMP) process which removes portions of the ILD layer 78 and the CESL 76 overlying the dummy gate stack 58. In some embodiments, the CMP process also removes hard mask layers 64a and 64b (as shown in FIG. 11) and exposes the dummy gate electrode 62.

An etching process is performed to remove the dummy gate electrode 62 and the dummy gate dielectric 60, resulting in gate trenches between corresponding gate spacers 72. The dummy gate stack 58 is removed using a selective etching process (e.g., selective dry etching, selective wet etching, or a combination thereof) that etches materials in the dummy gate stack 58 at a faster etch rate than it etches other materials (e.g., gate spacers 72 and/or the ILD layer 78).

Thereafter, high-k/gate structures 81 (i.e., replacement gate structures) are respectively formed in the gate trenches. The high-k/gate structures 81 may be the final gates of FinFETs. In FinFETs, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. The final gate structures each may be a high-k/metal gate (HKMG) stack; however other compositions are possible. In some embodiments, each of the high-k/gate structures 81 forms the gate associated with the three-sides of the channel region provided by the fin 104. Stated another way, each of the high-k/gate structures 81 wraps around the fin 104 on three sides. In various embodiments, the high-k/gate structure 81 includes a gate dielectric layer 82 lining the gate trench, a work function metal layer 84 formed over the gate dielectric layer 82, and a fill metal 86 formed over the work function metal layer 84 and filling a remainder of gate trenches. The gate dielectric layer 82 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (˜3.9). The work function metal layer 84 and/or the fill metal 86 used within high-k/gate structures 81 may include a metal, metal alloy, or metal silicide. Formation of the high-k/gate structures 81 may include multiple deposition processes to form various gate materials, one or more liner layers, and one or more CMP processes to remove excessive gate materials.

In some embodiments, the interfacial layer of the gate dielectric layer 82 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable methods. The high-k dielectric layer of the gate dielectric layer 82 may include hafnium oxide (HfO₂). Alternatively, the gate dielectric layer 82 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), or combinations thereof.

The work function metal layer 84 may include work function metals to provide a suitable work function for the high-k/gate structures 81. For an n-type FinFET, the work function metal layer 84 may include one or more n-type work function metals (N-metal). The n-type work function metals may exemplarily include but are not limited to, titanium aluminide (TiAl), titanium aluminum nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TIC), aluminum carbide (AlC)), aluminides, and/or other suitable materials. On the other hand, for a p-type FinFET, the work function metal layer 84 may include one or more p-type work function metals (P-metal). The p-type work function metals may exemplarily include but are not limited to, titanium nitride (TIN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 86 may exemplarily include but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, the semiconductor device 42 includes other layers or features not specifically illustrated. In some embodiments, back end of line (BEOL) processes are performed on the semiconductor device 42. In some embodiments, the semiconductor device 42 is formed by a non-replacement metal gate process or a gate-first process.

Based on the above discussions, it can be seen that the present disclosure offers methods of manufacturing the semiconductor device. The photoresist layer or photoresist composition includes the polymer containing the second repeating units. The second repeating units include the groups with larger volumes. Therefore, the patterned photoresist layer can have less volume loss and stronger mechanical strength, resulting in a broken-free and peeling-free pattern. After development, the patterned photoresist layer does not easily collapse, the pattern fidelity can be enhanced, and pattern wiggling can be reduced during a pattern transferring process. The patterned photoresist layer can be used to obtain a patterned layer with good quality and good CDU. The lithography performance can be improved.

In some embodiments, a method of manufacturing a semiconductor device includes the following operations. A photoresist layer is formed on a target layer, in which the photoresist layer includes a polymer including first repeating units and second repeating units. The first repeating units are

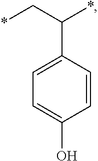

and the second repeating units are selected from the group consisting of

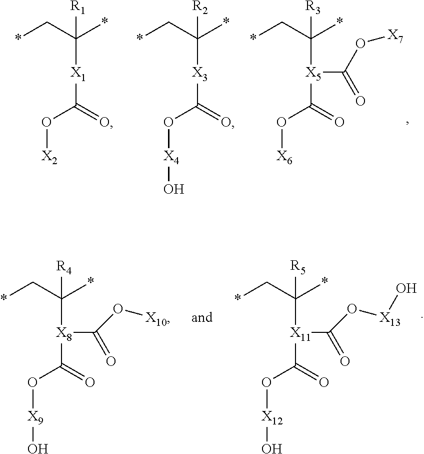

X₁ and X₃ are respectively an arylene group. X₅, X₈, and X₁₁ are respectively a trivalent functional group derived from an arene by removal of three hydrogen atoms. X₂, X₆, X₇, X₁₀, —X₄—OH, —X₉—OH, —X₁₂—OH, and —X₁₃—OH are respectively an acid labile group. R₁, R₂, R₃, R₄, and R₅ are respectively hydrogen or a methyl group. The photoresist layer is selectively exposed to a radiation. The photoresist layer is developed to form a patterned photoresist layer. The target layer is etched by using the patterned photoresist layer as an etching mask.

In some embodiments, a method of manufacturing a semiconductor device includes the following operations. A negative photoresist layer including a photoresist composition is formed over a substrate, in which the photoresist composition includes a photoactive compound and a polymer including first repeating units, second repeating units, and third repeating units. The first repeating units are

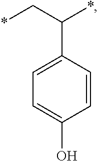

the second repeating units are selected from the group consisting of

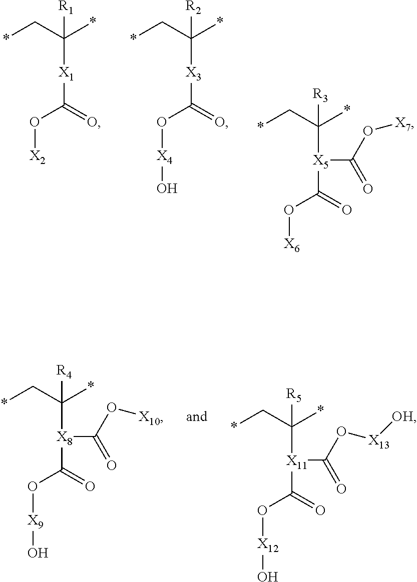

and the third repeating units are

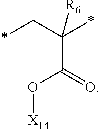

X₁ and X₃ are respectively an arylene group. X₅, X₈, and X₁₁ are respectively a trivalent functional group derived from an arene by removal of three hydrogen atoms. X₂, X₆, X₇, X₁₀, —X₄—OH, —X₉—OH, —X₁₂—OH, —X₁₃—OH, and X₁₄ are respectively an acid labile group. R₁, R₂, R₃, R₄, R₅, and R₆ are respectively hydrogen or a methyl group. The negative photoresist layer is exposed to a radiation to form at least one exposed portion and at least one unexposed portion. The at least one unexposed portion is removed to form a patterned photoresist layer.

In some embodiments, a photoresist composition includes a photoactive compound and a polymer including first repeating units and second repeating units. The first repeating units are

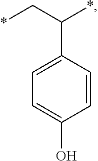

and the second repeating units are selected from the group consisting of

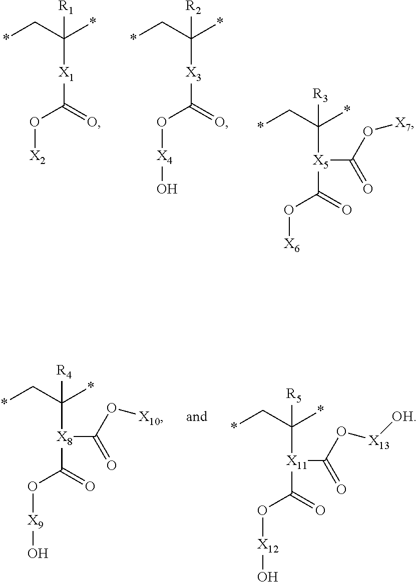

X₁ and X₃ are respectively an arylene group. X₅, X₈, and X₁₁ are respectively a trivalent functional group derived from an arene by removal of three hydrogen atoms. X₂, X₆. X₇, X₁₀, —X₄—OH, —X₉—OH, —X₁₂—OH, and —X₁₃—OH are respectively an acid labile group. R₁, R₂, R₃, R₄, and R₅ are respectively hydrogen or a methyl group.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a photoresist layer on a target layer, wherein the photoresist layer comprises a polymer comprising first repeating units and second repeating units, the first repeating units are 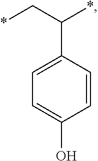
the second repeating units are selected from the group consisting of 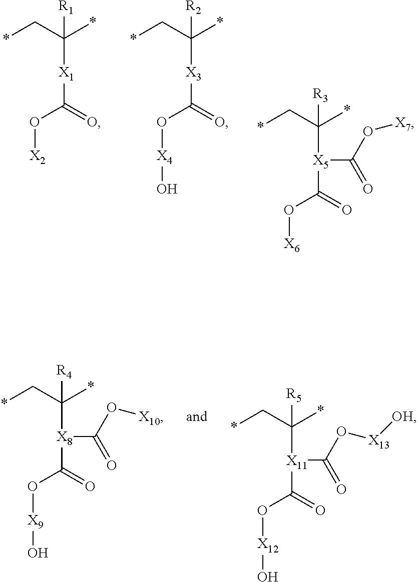
X₁ and X₃ are respectively an arylene group, X₅, X₈, and X₁₁ are respectively a trivalent functional group derived from an arene by removal of three hydrogen atoms, X₂, X₆, X₇, X₁₀, —X₄—OH, —X₉—OH, —X₁₂—OH, and —X₁₃—OH are respectively an acid labile group, and R₁, R₂, R₃, R₄, and R₅ are respectively hydrogen or a methyl group;
selectively exposing the photoresist layer to a radiation;
developing the photoresist layer to form a patterned photoresist layer; and
etching the target layer by using the patterned photoresist layer as an etching mask.

2. The method of claim 1, wherein X₁ and X₃ are respectively a phenylene group, and X₅, X₈, and X₁₁ are respectively a trivalent functional group derived from benzene by removal of three hydrogen atoms.

3. The method of claim 2, wherein the second repeating units are selected from the group consisting of 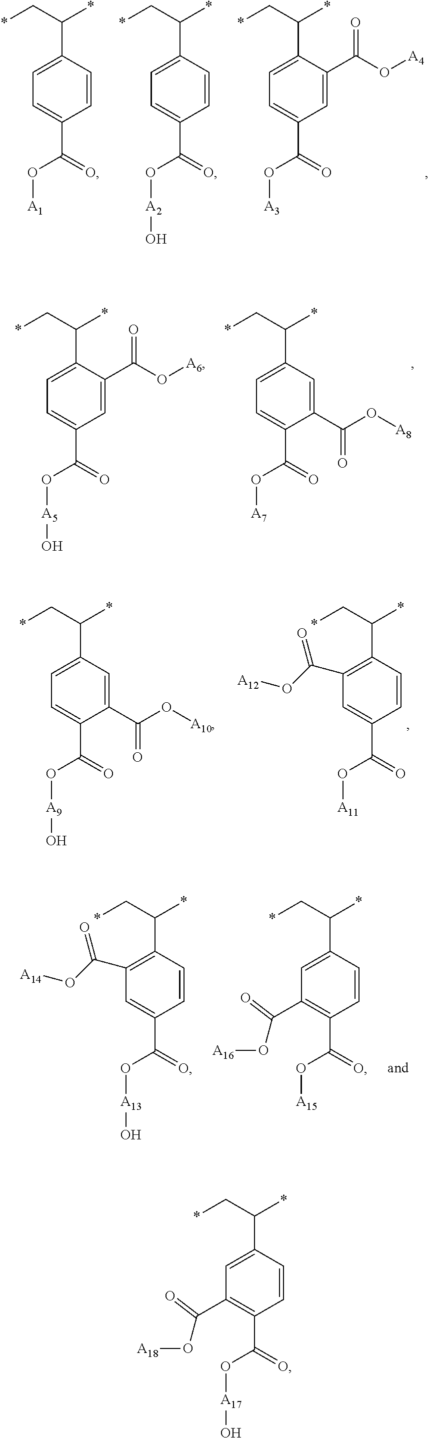
and A₁, A₃, A₄, A₆, A₇, As, A₁₀, A₁₁, A₁₂, A₁₄, A₁₅, A₁₆, A₁₈, -A₂-OH, -A₅-OH, -A₉-OH, -A₁₃-OH, and -A₁₇-OH are respectively an acid labile group.

4. The method of claim 1, wherein X₂, X₆, X₇, and X₁₀ are respectively a non-aromatic cycloalkyl group that is substituted by an alkyl group, a carboxyl group, a carbonyl group, or combinations thereof.

5. The method of claim 4, wherein X₂, X₆, X₇, and X₁₀ are respectively

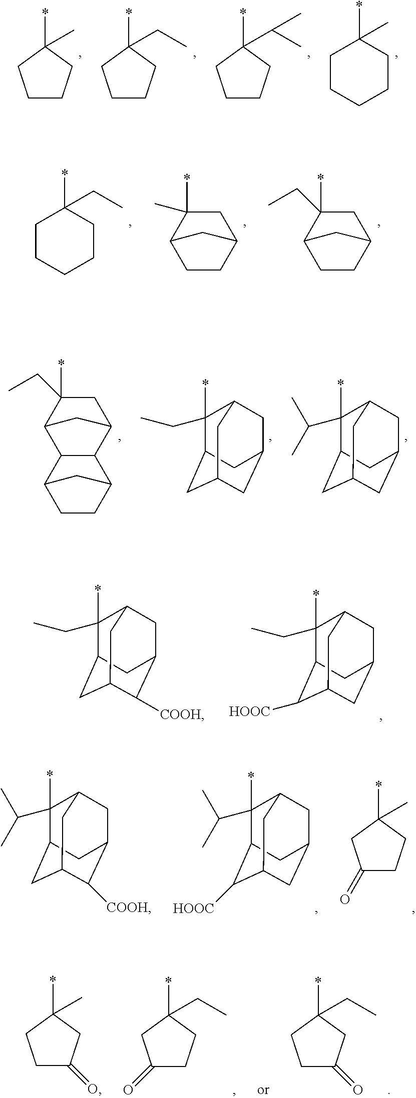

6. The method of claim 1, wherein X₄, X₉, X₁₂, and X₁₃ are respectively a bivalent functional group derived from a non-aromatic cycloalkyl group by removal of two hydrogen atoms, and the non-aromatic cycloalkyl group is substituted by an alkyl group, a carboxyl group, a carbonyl group, a hydroxyl group, or combinations thereof.

7. The method of claim 6, wherein —X₄—OH, —X₉—OH, —X₁₂—OH, and —X₁₃—OH are respectively

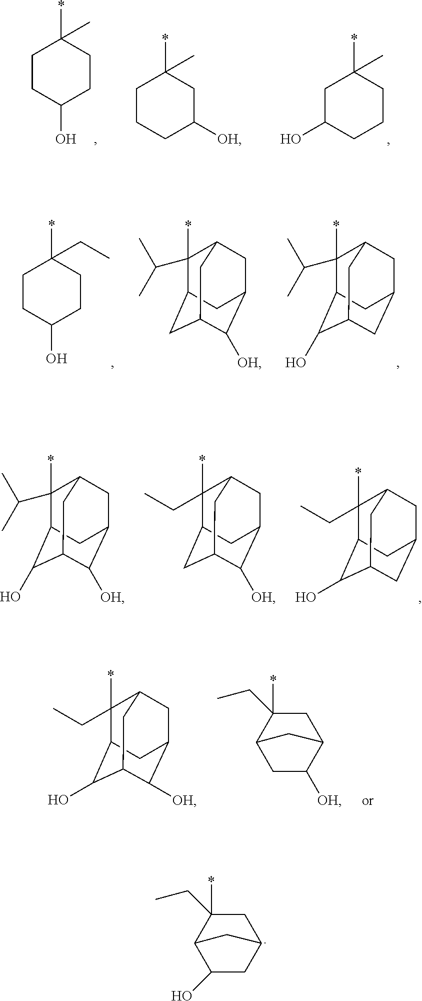

8. The method of claim 1, wherein the polymer further comprises third repeating units, the third repeating units are 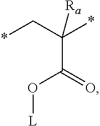
Rₐ is hydrogen or a methyl group, and L is a lactone moiety.

9. The method of claim 1, wherein the second repeating units are 40 wt % to 70 wt % based on a total polymer weight.

10. A method of manufacturing a semiconductor device, comprising:
forming a negative photoresist layer comprising a photoresist composition over a substrate, wherein the photoresist composition comprises a photoactive compound and a polymer comprising first repeating units, second repeating units, and third repeating units, the first repeating units are 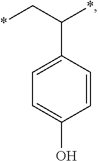
the second repeating units are selected from the group consisting of 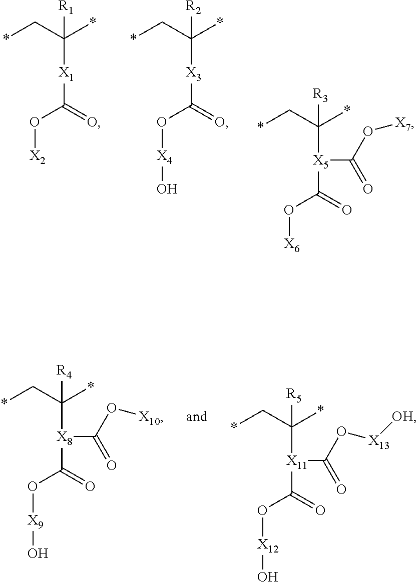
the third repeating units are 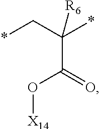
X₁ and X₃ are respectively an arylene group, X₅, X₈, and X₁₁ are respectively a trivalent functional group derived from an arene by removal of three hydrogen atoms, X₂, X₆, X₇, X₁₀, —X₄—OH, —X₉—OH, —X₁₂—OH, —X₁₃—OH, and X₁₄ are respectively an acid labile group, and R₁, R₂, R₃, R₄, R₅, and R₆ are respectively hydrogen or a methyl group;
exposing the negative photoresist layer to a radiation to form at least one exposed portion and at least one unexposed portion; and
removing the at least one unexposed portion to form a patterned photoresist layer.

11. The method of claim 10, wherein the second repeating units and the third repeating units are 40 wt % to 60 wt % based on a total polymer weight.

12. The method of claim 10, wherein the patterned photoresist layer has U-shaped portions and connecting portions between the U-shaped portions in a top view.

13. The method of claim 10, wherein X₂, X₆, X₇, X₁₀, —X₄—OH, —X₉—OH, —X₁₂—OH, —X₁₃—OH, and X₁₄ are respectively a non-aromatic cycloalkyl group that is substituted by an alkyl group, a carboxyl group, a carbonyl group, a hydroxyl group, or combinations thereof.

14. The method of claim 13, wherein the non-aromatic cycloalkyl group is monocyclic or polycyclic.

15. The method of claim 10, wherein the polymer further comprises fourth repeating units, the fourth repeating units are 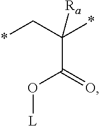
Rₐ is hydrogen or a methyl group, and L is a lactone moiety.

16. A photoresist composition, comprising:
a photoactive compound; and
a polymer comprising first repeating units and second repeating units, wherein the first repeating units are 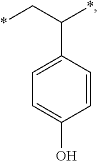
the second repeating units are selected from the group consisting of 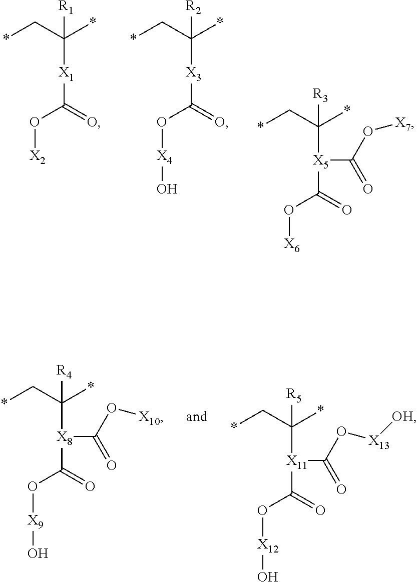
X₁ and X₃ are respectively an arylene group, X₅, X₈, and X₁₁ are respectively a trivalent functional group derived from an arene by removal of three hydrogen atoms, X₂, X₆, X₇, X₁₀, —X₄—OH, —X₉—OH, —X₁₂—OH, and —X₁₃—OH are respectively an acid labile group, and R₁, R₂, R₃, R₄, and R₅ are respectively hydrogen or a methyl group.

17. The photoresist composition of claim 16, wherein the polymer further comprises third repeating units, the third repeating units are 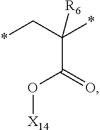
R₆ is respectively hydrogen or a methyl group, and X₁₄ is an acid labile group.

18. The photoresist composition of claim 16, wherein the polymer further comprises third repeating units, the third repeating units are 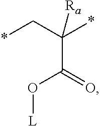
Rₐ is hydrogen or a methyl group, and L is a lactone moiety.

19. The photoresist composition of claim 16, wherein X₁ and X₃ are respectively a phenylene group, and X₅, X₈, and X₁₁ are respectively a trivalent functional group derived from benzene by removal of three hydrogen atoms.

20. The photoresist composition of claim 16, further comprising a solvent.
